(19) United States
(12) Patent Application Publication
(10) Pub. No.: US 2013/0186677 A1
(43) Pub. Date: Jul. 25, 2013

(54) PRINTED CIRCUIT BOARD AND METHOD OF MANUFACTURING THE SAME

(71) Applicant: Jong-Jin LEE, Daejeon (KR)

(72) Inventor: Jong-Jin LEE, Daejeon (KR)

(73) Assignee: SAMSUNG ELECTRO-MECHANICS CO., LTD., Suwon (KR)

(21) Appl. No.: 13/788,916

(22) Filed: Mar. 7, 2013

Related U.S. Application Data
(63) Continuation of application No. 12/358,543, filed on Jan. 23, 2009.

(30) Foreign Application Priority Data
Sep. 8, 2008 (KR) 10-2008-0088177

(51) Int. Cl. H05K 3/00; H05K 1/02

(52) U.S. Cl. CPC H05K 3/0058; H05K 1/0271
USPC 174/257; 216/20

(57) ABSTRACT

A printed circuit board and a method of manufacturing the printed circuit board are disclosed. In an embodiment of the present invention, the method of manufacturing a printed circuit board can include: providing a pair of conductive layers, in which roughness of one surface of one of the pair of conductive layers is different from roughness of one surface of the other of the pair of conductive layers; and stacking the pair of the conductive layers on a dielectric layer such that one surface of one of the pair of conductive layers faces one surface of the dielectric layer and one surface of the other of the pair of conductive layers faces another surface of the dielectric layer.

### CROSS-REFERENCE TO RELATED APPLICATIONS

This application claims the benefit of Korean Patent Application No. 10-2008-0088177, filed with the Korean Intellectual Property Office on Sep. 8, 2008, the disclosure of which is incorporated herein by reference in its entirety.

### BACKGROUND

1. Technical Field

The present invention relates to a printed circuit board and a method of manufacturing the printed circuit board.

2. Description of the Related Art

With the development of electronic products, printed circuit boards are becoming increasingly thinner, and reducing the warpage of the printed circuit board has become one of the major tasks.

During the packaging process of mounting semiconductor chips on a printed circuit board, a number of heating and cooling processes cause the warpage in the printed circuit board due to the reduced thickness of the printed circuit board. Furthermore, as the package, in which the printed circuit board and semiconductor chip are assembled, is implemented and used in an electronic product, the repeated heating and cooling associated with the use cause the warpage of the printed circuit board periodically, significantly deteriorating the product reliability.

FIG. 1 is a cross sectional view illustrating a printed circuit board 10 in accordance with the related art. Referring to FIG. 1, the printed circuit board 10 according to the related art includes a dielectric layer 20 and metal layers 30 and 40, each of which is stacked on each surface of the dielectric layer 20. Here, each of the metal layers 30 and 40 is substantially the same in surface roughness.

As such, the printed circuit board 10 in accordance with the related art uses the metal layers 30 and 40 that have the same surface roughness. Therefore, as illustrated in FIG. 1, if the residual ratios of the metal layers 30 and 40 are asymmetric due to the patterning of the metal layers 30 and 40, the heat generated during the packaging process of mounting a semiconductor chip and by the use of the electronic product causes the printed circuit board 10 to warp toward the metal layer 30 having a smaller residual ratio.

### SUMMARY

The present invention provides a printed circuit board and a method of manufacturing the printed circuit board that can reduce warpage caused by the heat.

An aspect of the present invention provides a method of manufacturing a printed circuit board. In an embodiment of the present invention, the method of manufacturing a printed circuit board can include: providing a pair of conductive layers, in which roughness of one surface of one of the pair of conductive layers is different from roughness of one surface of the other of the pair of conductive layers; and stacking the pair of the conductive layers on a dielectric layer such that one surface of one of the pair of conductive layers faces one surface of the dielectric layer and one surface of the other of the pair of conductive layers faces another surface of the dielectric layer.

Here, the conductive layer can be copper foil.

The dielectric layer can be made of a material including epoxy resin.

Another aspect of the present invention provides a printed circuit board. In an embodiment of the present invention, the printed circuit board can include: a dielectric layer, which is made of a material including epoxy resin; and a pair of copper foil films, in which each of the copper foil films is stacked on each surface of the dielectric layer such that one surface of one of the pair of copper foil films faces one surface of the dielectric layer and one surface of the other of the pair of copper foil films faces another surface of the dielectric layer and roughness of one surface of one of the pair of copper foil films is different from roughness of one surface of the other of the pair of copper foil films.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross sectional view illustrating a printed circuit board in accordance with the related art.

FIG. 2 is a flowchart illustrating a method of manufacturing a printed circuit board in accordance with an embodiment of the present invention.

FIGS. 3 and 4 are cross sectional views illustrating each process of manufacturing a printed circuit board in accordance with an embodiment of the present invention.

FIG. 5 is a cross sectional view illustrating a printed circuit board in accordance with another embodiment of the present invention.

### DETAILED DESCRIPTION

Certain embodiments of the present invention will be described below in detail with reference to the accompanying drawings. For better understanding overall in describing aspects of the present invention, the same reference numerals are used for the same means, regardless of the figure number.

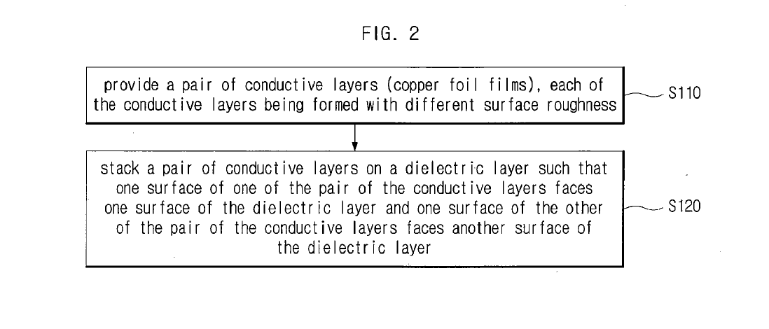

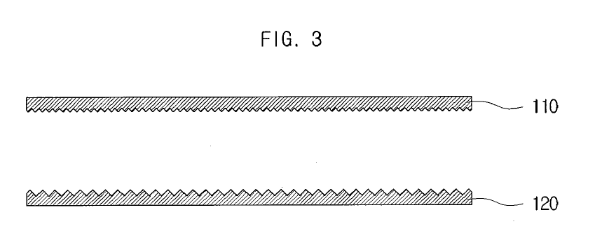

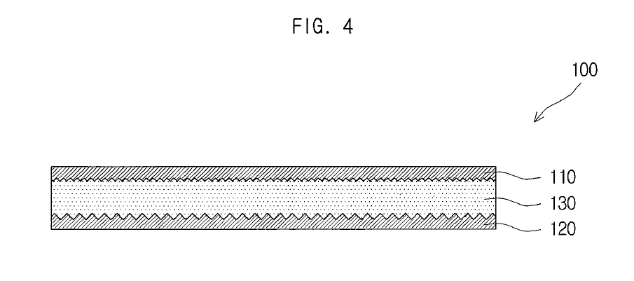

FIG. 2 is a flowchart illustrating a method of manufacturing a printed circuit board in accordance with an embodiment of the present invention, and FIGS. 3 and 4 are cross sectional views illustrating each process of manufacturing a printed circuit board in accordance with an embodiment of the present invention.

In an embodiment of the present invention, a method of manufacturing a printed circuit board can include: providing a pair of conductive layers 110 and 120, in which roughness of one surface of one of the pair of conductive layers 110 and 120 is different from roughness of one surface of the other of the pair of conductive layers 110 and 120; and stacking the pair of conductive layers 110 and 120 on a dielectric layer 130 such that one surface of one of the pair of conductive layers 110 and 120 faces one surface of the dielectric layer 130 and one surface of the other of the pair of conductive layers 110 and 120 faces another surface of the dielectric layer 130.

As such, the warpage of the printed circuit board 100, caused by the heat generated during the packaging process of mounting a semiconductor chip on the printed circuit board 100 or while an electronic product in which the printed circuit board 100 is implemented is used, can be reduced in accordance with the present embodiment.

Below, each process will be described in more detail by referring to FIGS. 2 to 4.

First of all, as illustrated in FIG. 3, a pair of conductive layers 110 and 120, in which roughness of one surface of one of the pair of conductive layers is different from roughness of one surface of the other of the pair of conductive layers, is provided (S110). Here, the pair of conductive layers 110 and 120 is copper foil, and one surface of each of the conductive layers 110 and 120 is formed with a different surface roughness.

In other words, after one surface of each of the conductive layers, i.e., copper foil, 110 and 120 is roughened to have a surface roughness, an anchoring process, for example, can be performed to improve its adhesion strength with the dielectric layer 130 (in FIG. 4).

Here, one surface of each of the conductive layers 110 and 120 has a different surface roughness. As a result, if each of the conductive layers 110 and 120 is compressed toward the dielectric layer 130 (in FIG. 4), the rougher conductive layer 120 can be adhered to the dielectric layer 130 (in FIG. 4) more strongly than the less rough conductive layer does. Moreover, the surface of the dielectric layer 130 (in FIG. 4) that is in contact with the rougher conductive layer 120 can have a stronger lateral resistance from warpage.

Next, as illustrated in FIG. 4, the pair of conductive layers 110 and 120 is stacked on the dielectric layer 130 such that one surface of one of the pair of conductive layers 110 and 120 faces one surface of the dielectric layer 130 and one surface of the other of the pair of conductive layers 110 and 120 faces another surface of the dielectric layer 130 (S120). In other words, after stacking the pair of conductive layers 110 and 120, in which roughness of one surface of one of the pair of conductive layers is different from roughness of one surface of the other of the pair of conductive layers, on the dielectric layer 130, the dielectric layer 130 can be interposed between the conductive layers 110 and 120, and the conductive layers 110 and 120 and the dielectric layer 130 can be compressed against one another in a high temperature environment.

Since the dielectric layer 130 can be made of epoxy resin being in a half-hardening state, one surface, which is formed with a surface roughness, of each of the conductive layer 110 and 120 can be adhered to the dielectric layer 130 more efficiently and easily.

Moreover, by stacking the pair of conductive layers 110 and 120 on the dielectric layer 130, as described above, the rougher conductive layer can be adhered to the dielectric layer more strongly than the less rough conductive layer does, and the surface of the dielectric layer that is in contact with the rougher conductive layer can have a stronger lateral resistance from warpage. As a result, even if the rougher conductive layer is expanded far more than the less rough conductive layer due to the heat applied to the printed circuit board 100, the difference in expansion can be cancelled out by the above adhesion strength and lateral resistance from warpage.

Below, the above-mentioned principle will be described in more detail by comparing the related art with the present embodiment.

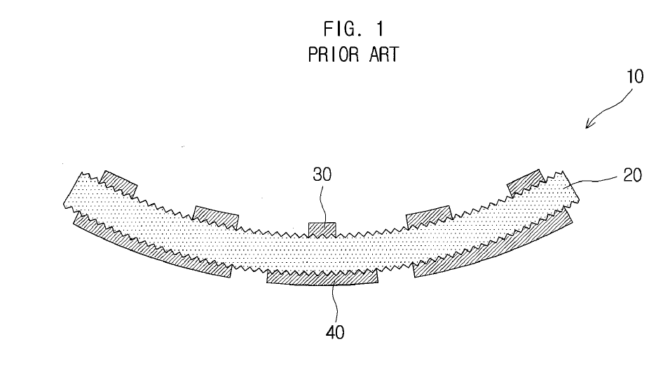

In case of the printed circuit board 10 (in FIG. 1) according to the related art, each of the metal layers 30 and 40 (in FIG. 1) has the same surface roughness. As a result, if the metal layers 30 and 40 (in FIG. 1) being left on each surface of the dielectric layer 20 (in FIG. 1) are different from each other due to the patterning of the metal layers 30 and 40 (in FIG. 1), the metal layer 40 (in FIG. 1) having a greater residual ratio may be expended greater than the metal layer 30 (in FIG. 1) having a smaller residual ratio when heated by the heat generated during the packaging process or by the use of the electronic product. Therefore, the printed circuit board 10 (in FIG. 1) may be wrapped toward the metal layer 30 (in FIG. 1) having a smaller residual ratio.

However, in accordance with the present embodiment, by forming one surface of each of the conductive layers 110 and 120 with a different surface roughness, as described above, the difference in expansion caused by the heat can be minimized by controlling the lateral resistance of the dielectric layer 130. As a result, when forming a circuit pattern by etching each of the conductive layers 110 and 120, thereby making a residual amount of the rougher conductive layer 120 greater than a residual amount of the less rough conductive layer 110, even if the rougher conductive layer 120 is expanded far more than the less rough conductive layer 110, the difference in expansion can be cancelled out by the stronger adhesion strength, created by the rougher conductive layer 120 and the dielectric layer 130, and the lateral resistance of the dielectric layer 130 from warpage, and thus the warpage of the printed circuit board 100 can be reduced.

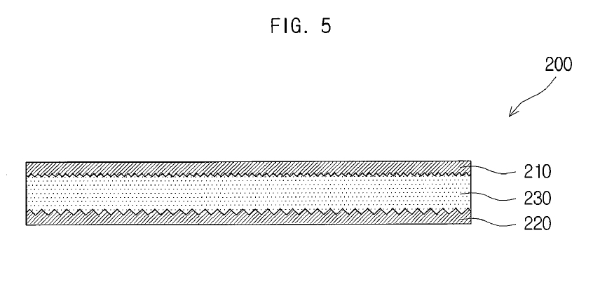

Next, in accordance with another aspect of the present invention, a printed circuit board 200 will be described by referring to FIG. 5.

FIG. 5 is a cross sectional view illustrating a printed circuit board 200 in accordance with another embodiment of the present invention.

In this embodiment, the printed circuit board 200 can include: a dielectric layer 230, which is made of a material including epoxy resin; and a pair of copper foil films 210 and 220, in which each of the copper foil films is stacked on each surface of the dielectric layer 230 such that one surface of one of the pair of copper foil films 210 and 220 faces one surface of the dielectric layer 230 and one surface of the other of the pair of the copper foil films 210 and 220 faces another surface of the dielectric layer 230 and roughness of one surface of one of the pair of copper foil films 210 and 220 is different from roughness of one surface of the other of the pair of copper foil films 210 and 220.

As such, the warpage of the printed circuit board 200, caused by the heat generated during the packaging process of mounting a semiconductor chip on the printed circuit board 200 or while an electronic product in which the printed circuit board 200 is implemented is used, can be reduced in accordance with the present embodiment.

Below, each component will be described in more detail with reference to FIG. 5.

The dielectric layer 230 can be made of a material including epoxy resin. The dielectric layer 230 being in a half-hardening state can be compressed with the copper foil films 210 and 220, which will be described in the following description, and heated and hardened at the same time. As such, by using such dielectric layer 230 being in a half-hardening state, the dielectric layer 230 can be adhered to the copper foil films 210 and 220 more efficiently and easily.

Roughness of one surface of one of the pair of copper foil films 210 and 220 is formed differently from roughness of one surface of the other of the pair of copper foil films 210 and 220, and the pair of copper foil films is stacked on the dielectric layer 230 such that one surface of one of the pair of copper foil films faces one surface of the dielectric layer 230 and one surface of the other of the pair of copper foil films faces another surface of the dielectric layer 230. In other words, one surface of each of the copper foil films 210 and 220 can be formed with a different surface roughness, and one surface of one of the pair of copper foil films 210 and 220 faces one surface of the dielectric layer 230 and one surface of the other of the pair of copper foil films 210 and 220 faces another surface of the dielectric layer 230. As such, the dielectric layer 230 can be interposed between the copper foil films 210 and 220, and then the pair of copper foil films 210 and 220 and the dielectric layer 230 can be formed as the printed circuit board 200, as described above, by being compressed in a high temperature environment.

In such printed circuit board 200, as the copper foil films 210 and 220, formed with a different surface roughness, are disposed on both sides of the dielectric layer 230, even if the residual amounts of the copper foil films 210 and 220 is different due to the patterning, the adhesion strength, created by the copper foil film 220 and the dielectric layer 230, and the lateral resistance of the dielectric layer 230 from warpage can be increased by increasing a surface roughness of the copper foil film 220 having a greater residual amount. Therefore, by the above adhesion strength and lateral resistance from warpage, the expansion of the copper foil film 220 having a greater residual amount can be controlled, and thus the warpage of the printed circuit board 200 caused by the heat can be reduced.

According to certain aspects of the present invention as set forth above, the warpage of a printed circuit board, caused by the heat generated during the packaging process of mounting a semiconductor chip on the printed circuit board or while an electronic product in which the printed circuit board is implemented is used, can be reduced.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention. As such, many embodiments other than those set forth above can be found in the appended claims.

1-4. (canceled)

5. A printed circuit board comprising:
a dielectric layer;
a first circuit pattern being formed on the dielectric layer such that a first surface of the first copper foil faces one surface of the dielectric layer; and
a second circuit pattern being stacked on the dielectric layer such that a second surface of the second copper foil faces another surface of the dielectric layer,
wherein roughness of the first surface of the first circuit pattern being larger than roughness of the second surface of the second circuit pattern, and
the dielectric layer is positioned at a center of the printed circuit board.

6. The printed circuit board of claim 5, wherein a volume of the first circuit pattern is greater than a volume of the second circuit pattern.

7. The printed circuit board of claim 5, wherein the first circuit pattern is adhered to the dielectric layer more strongly than the second circuit pattern does.

8. The printed circuit board of claim 5, wherein the dielectric layer is a single layer.

9. The printed circuit board of claim 5, wherein the dielectric layer is made of a material including epoxy.

10. The printed circuit board of claim 5, wherein the first circuit pattern and the second circuit pattern are made of a material including copper.

11. A method of manufacturing a printed circuit board, the method comprising:
providing a first conductive layer and a second conductive layer, roughness of a first surface of the first conductive layer being larger than roughness of a second surface of the second conductive layer;
stacking the first conductive layer and the second conductive layer on a dielectric layer such that the first surface of the first conductive layer faces one surface of the dielectric layer and the second surface of the second conductive layer faces another surface of the dielectric layer; and
forming a first circuit pattern and a second circuit pattern by etching each of the first conductive layer and the second conductive layer,
wherein the dielectric layer is positioned at a center of the printed circuit board.

12. The method of claim 11, wherein the forming of the first circuit pattern and the second circuit pattern is performed by etching each of the first conductive layer and the second conductive layer such that a residual amount of the first conductive layer is greater than a residual amount of the second conductive layer.

13. The method of claim 11, further comprising:
compressing the first conductive layer and the second conductive layer toward the dielectric layer such that the first conductive layer is adhered to the dielectric layer more strongly than the second conductive layer does between the stacking of the first conductive layer and the second conductive layer and the forming of the first circuit pattern and the second circuit pattern.

14. The method of claim 11, wherein the dielectric layer is a single layer.

15. The method of claim 11, wherein the dielectric layer is made of a material including epoxy.

16. The method of claim 11, wherein the first conductive layer and the second conductive layer are a copper foil.
